(19) United States
(12) Patent Application Publication
(10) Pub. No.: US 2025/0253118 A1
(43) Pub. Date: Aug. 7, 2025

(54) Imaging System and Imaging Method

(71) Applicant: Hitachi High-Tech Corporation, Minato-ku, Tokyo (JP)

(72) Inventors: Shuji KATSUTA, Tokyo (JP); Hiromi MISE, Tokyo (JP); Shuntaro ITO, Tokyo (JP)

(21) Appl. No.: 18/855,724

(22) PCT Filed: Apr. 22, 2022
(86) PCT No.: PCT/JP2022/018509

§ 371 Date: Oct. 10, 2024

(51) Int. Cl. H01J 37/20; H01J 37/147; H01J 37/244

(52) U.S. Cl. CPC H01J 37/20; H01J 37/147; H01J 37/244

(57) ABSTRACT

The present invention improves throughput before observation of a lamella is completed, and also automatically makes corrections even when the lamella is greatly inclined. An imaging system 10 of the present disclosure comprises: a surface shape measurement device 3 which measures three-dimensional coordinate information about the surface shape of a lamella having a layered structure; a computer system 1 which, on the basis of the three-dimensional coordinate information measured by the surface shape measurement device 3, calculates correction information for correcting the angle and height of the lamella during imaging of the lamella, and which transmits the calculated correction information; and a charged particle beam device 4 which receives the correction information, corrects the angle and height of the lamella on the basis of the correction information, and irradiates the lamella of which the angle and height have been corrected with a charged particle beam to image the lamella.

### TECHNICAL FIELD

The present disclosure relates to an imaging system and an imaging method, and to an imaging system and an imaging method for imaging a lamella having a laminated structure.

### BACKGROUND ART

With the progress of miniaturization of a semiconductor device, an influence of line edge roughness (LER) on device performance is increasing. Accordingly, it is considered that needs for observation using a transmission electron microscope (TEM) capable of performing defect analysis and length measurement on a sub-nanometer scale increase. With the increase in the needs for observation using the TEM, automation of a series of steps from processing of a sample by an FIB (Focused Ion Beam) processing device to observation using TEM and improvement of throughput are required.

In a series of steps up to observation using the TEM, there is a procedure of adjusting an angle and a height of a stage on which the lamella is mounted, for each of a plurality of lamellae placed on a TEM mesh, to conditions that provide a higher degree of resolution. A method for automating the above steps are studied in the past. The lamella described here refers to a thin sample for observation with the TEM.

For example, Patent Literature 1 discloses a method for automatically and highly accurately adjusting an inclination angle of a stage to a desired crystal orientation of a sample using an image of a diffraction pattern including a Kikuchi line.

Patent Literature 2 discloses a method for obtaining a height distribution of a sample by performing multi-resolution analysis by a wavelet transform or a discrete wavelet transform.

### CITATION LIST

### Patent Literature

PTL 1: WO2020/235091
PTL 2: WO2020/075241

### SUMMARY OF INVENTION

### Technical Problem

Adjustment of the angle of the stage by the method described in Patent Literature 1 and Z-axis adjustment of the stage by the method described in Patent Literature 2 can achieve sufficient accuracy for performing accurate defect analysis and length measurement. However, since the adjustment requires a long time, a throughput until the observation using the TEM is completed may decrease. In addition, particularly in the adjustment of the angle of the stage, a range of automatically adjustable angles is narrow, and if the lamella is placed on the TEM mesh and inclined significantly, automatic correction may not be performed.

Therefore, an object of the present disclosure is to provide an imaging system and an imaging method that can improve a throughput until observation of a lamella is completed and can automatically correct the lamella even if it is significantly inclined.

### Solution to Problem

In order to solve the above problems, an imaging system of the present disclosure includes: a surface shape measurement device configured to measure three-dimensional coordinate information of a surface shape of a lamella having a laminated structure; a computer system configured to calculate, based on the three-dimensional coordinate information measured by the surface shape measurement device, correction information for correcting an angle and a height of the lamella during imaging of the lamella, and to transmit the calculated correction information; and a charged particle beam device configured to receive the correction information, correct the angle and the height of the lamella based on the correction information, and irradiate the lamella of which the angle and the height are corrected with a charged particle beam to image the lamella.

### Advantageous Effects of Invention

According to the present disclosure, it is possible to improve a throughput until observation of a lamella is completed, and also automatically correct the lamella even when the lamella is greatly inclined.

Problems, configurations, and effects other than those described above will be clarified by the following description of an embodiment.

### BRIEF DESCRIPTION OF DRAWINGS

FIG. 1 is a diagram showing an overall configuration of an imaging system according to a first embodiment.

FIG. 2 is a flowchart showing a process performed by the imaging system according to the first embodiment.

FIG. 3 is a functional block diagram of device-to-device cooperation software according to the first embodiment.

FIG. 4 is a configuration diagram of data stored in a storage device of a computer system according to the first embodiment.

FIG. 5 is a flowchart showing a calculation method for calculating TEM stage correction information based on surface shape measurement data according to the first embodiment.

FIG. 6 is a flowchart showing a calculation method for calculating TEM stage correction information based on surface shape measurement data according to a second embodiment.

FIG. 7 is a diagram showing an automatically adjustable range of an angle (α·β) of the TEM stage.

FIG. 8 is a diagram showing an operation of automatic adjustment of the angle (α·β) of the TEM stage.

FIG. 9 is a diagram showing a search operation for adjusting a lamella height.

### DESCRIPTION OF EMBODIMENTS

Embodiments according to the disclosure will be described in detail with reference to the drawings. In the following embodiments, it is needless to say that a configuration (including steps in a flowchart) is not necessarily essential unless otherwise specified or unless clearly considered to be essential in principle. Hereinafter, preferred embodiments of the present disclosure will be described with reference to the drawings.

In the drawings, the same components are denoted by the same reference numerals in principle, and repeated description thereof is omitted. In order to facilitate understanding of the present disclosure, expressions of components in the drawings may not represent the actual position, size, shape, range, and the like.

For the sake of description, in the case of describing processing executed by a program, a program, a function, a processing unit, and the like may be described as a main body, but a main body of hardware thereof is a processor, or a controller, a device, a computer, a system or the like implemented with a processor. The computer executes processing according to a program read onto a memory by a processor while appropriately using resources such as a memory and a communication interface. Accordingly, a predetermined function, processing unit, and the like are implemented. The processor is implemented with, for example a semiconductor device such as a CPU or a GPU. The processor is implemented by a device or a circuit capable of performing a predetermined calculation. Processing can be executed not only by a software program but also by a dedicated circuit. The dedicated circuit may be an FPGA, an ASIC, a CPLD, or the like.

The program may be installed as data in a target computer in advance, or may be distributed as data from a program source to a target computer and installed. The program source may be a program distribution server on a communication network, or may be a non-transitory computer-readable storage medium (for example, a memory card or a magnetic disk). The program may include a plurality of modules. The computer system may include a plurality of devices. The computer system may be implemented as a cloud computing system or the like.

The various kinds of data and information are configured with a structure such as a table or a list, but are not limited thereto. The expressions such as identification information, identifier, ID, name, and number can be mutually replaced.

For description, an X direction, a Y direction, a Z direction, and the like may be used. These directions (in other words, axes) intersect, in particular, are orthogonal to one another. In particular, the Z direction is a direction corresponding to up and down, height, depth, thickness, and the like. Unless otherwise specified, a coordinate system of a three-dimensional space will be described on an assumption that the coordinate system is a left-hand system. In addition, α, β, γ, and the like may be used to describe a rotation direction in space. These directions represent Euler angles [rad] rotating around an X-axis, a Y-axis, and a Z-axis, respectively.

### First Embodiment

### <Imaging System>

An imaging system 10 according to a first embodiment is the imaging system 10 that measures angles and heights of a plurality of lamellae displaced on a TEM mesh, calculates correction information for correcting an angle and a height of a TEM stage 5, and automatically adjusts the TEM stage 5 of a charged particle beam device 4 based on the correction information. The TEM mesh is a mesh-shaped member in which the plurality of lamellae can be displaced.

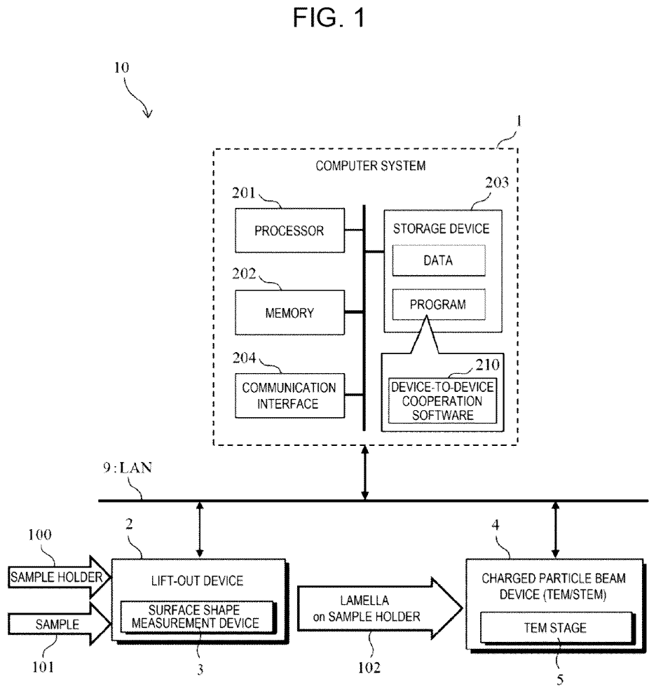

FIG. 1 is a diagram showing an overall configuration of an imaging system according to the first embodiment. The imaging system 10 of FIG. 1 includes a computer system 1, a lift-out device 2, and the charged particle beam device 4. The computer system 1, the lift-out device 2, and the charged particle beam device 4 are communicably connected to one another via a communication network such as a LAN 9. Even when the computer system 1, the lift-out device 2, and the charged particle beam device 4 are not connected to one another via the above-described communication network, for example, a user may store data and information in a storage medium such as a memory card and carry the storage medium to input and output the data and the information among the computer system 1, the lift-out device 2, and the charged particle beam device 4.

The computer system 1 includes a processor 201, a memory 202, a storage device 203, a communication interface 204, and the like, and these are connected one another via a bus. The storage device 203 stores various programs and data. The program includes a device-to-device cooperation software 210 to be described later. The communication interface 204 is communicably connected to the LAN 9.

The computer system 1 does not need to exist as independent hardware, and may be, for example, a PC common to a control PC of the lift-out device 2 and the charged particle beam device 4.

The lift-out device 2 is a device that picks up the lamella and places it on a TEM mesh fixed on a sample holder 100. The lamella is obtained by processing an observation portion from a sample 101 into a thin sample for observation by the charged particle beam device 4 by an FIB processing device or the like, and has a laminated structure.

A device for creating the lamella, such as the FIB processing device, may be incorporated in the lift-out device 2. In this case, the sample 101 is put into the lift-out device 2 in a state in which the observation portion is not processed into the lamella.

A surface shape measurement device 3 is incorporated in the lift-out device 2. The surface shape measurement device 3 satisfies the following two requirements. The first is that three-dimensional coordinate information (X,Y,Z) can be acquired, and the second is that sufficient spatial resolution (three-dimensional coordinate information of at least three or more points) for obtaining an angle and a height of a measurement target can be obtained. Specifically, examples thereof include a white light interference microscope (CSI), a laser confocal microscope (LSM), an optical microscope or an electron microscope (X,Y) combined with a height sensor (Z), and optical or electron microscopes that perform imaging in a plurality of directions or using a plurality of detectors to obtain three-dimensional coordinates.

Since the white light interference microscope of the surface shape measurement device 3 has a high measurement speed and can obtain sufficient spatial resolution for measuring a surface shape of the lamella (particularly in a Z-axis direction), it can be said that the white light interference microscope is a suitable device in the present embodiment.

The charged particle beam device 4 is a device for observing a plurality of lamellae placed on the TEM mesh by the lift-out device 2. The charged particle beam device 4 receives a sample holder 102 to which the TEM mesh on which the plurality of lamellae are placed is fixed, and irradiates the plurality of lamella placed on the TEM mesh with a charged particle beam to perform imaging of the plurality of lamellae. The charged particle beam device 4 is a transmission charged particle beam device, and is, for example, a transmission electron microscope (TEM) or a scanning transmission electron microscope (STEM). Here, the TEM and/or STEM are described as TEM.

### <Method for Imaging Lamella by Imaging System 10>

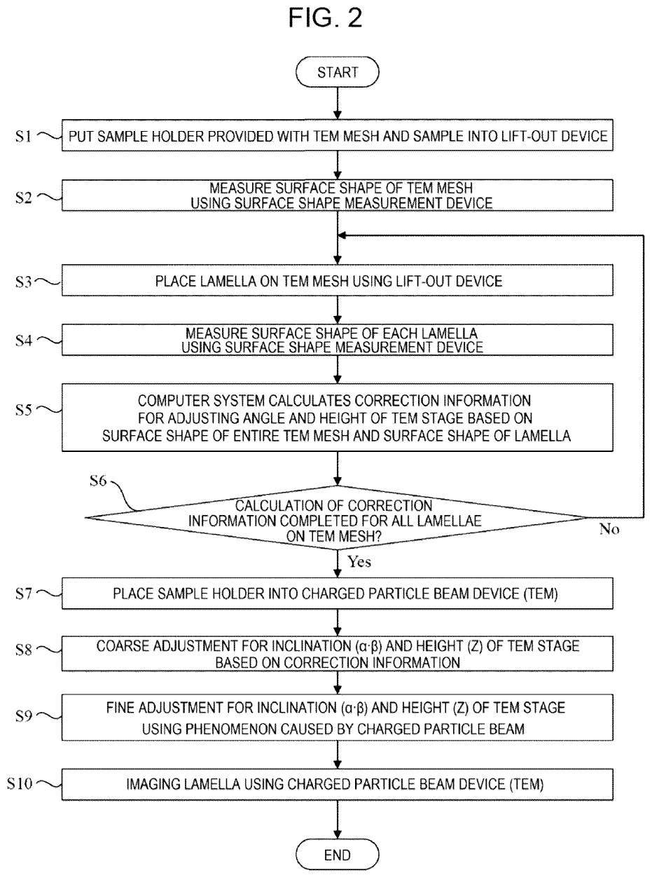

FIG. 2 is a flowchart showing processing (including work performed by the user) executed in the imaging system according to the first embodiment. The method for imaging the lamella using the imaging system 10 will be described with reference to FIG. 2.

In step S1, the user, an automatic transfer device, or the like puts the sample holder 100 and the sample 101 to which the TEM mesh is fixed into the lift-out device 2. The sample 101 corresponds to a semiconductor wafer or the like in which the lamella is formed by an FIB processing device.

In step S2, the surface shape measurement device 3 measures a surface shape of the entire TEM mesh fixed to the sample holder 100. In step S2, the surface shape of the entire TEM mesh is measured. The TEM mesh may be divided into a plurality of sections, and the surface shape may be measured for each of the plurality of sections, or the surface shape may be measured for each portion where the lamella is placed.

In step S3, the lift-out device 2 picks up the lamella from the sample 101 and places it on the TEM mesh. The lamella is picked up using a manipulator or tweezers.

In step S4, the surface shape measurement device 3 measures the surface shape of each lamella placed on the TEM mesh. An angle and a height used as a reference when measuring the surface shape of the lamella may be those obtained by using a frame of the TEM mesh or an initially calibrated value. A magnification for measuring the surface shape of each lamella placed on the TEM mesh in step S4 may be higher than a magnification for measuring the surface shape of the entire TEM mesh in step S2.

In step S5, the computer system 1 calculates correction information for adjusting the angle and the height of the TEM stage 5 of the charged particle beam device 4 based on the surface shape of the TEM mesh measured in step S2 and the surface shape of the lamella measured in step S4. A specific calculation method will be described later in <Calculation Method of Correction Information for TEM Stage 5>. Then, the computer system 1 transmits the calculated correction information to the charged particle beam device 4.

In step S6, the computer system 1 determines whether the calculation of the correction information is completed for all the lamellae placed on the TEM mesh. When the computer system 1 determines that the calculation of the correction information is not completed for all the lamellae placed on the TEM mesh (step S6: No), the processing returns to the processing of step S3, and when it is determined that the calculation of the correction information is completed for all lamellae placed on the TEM mesh (step S6: Yes), the computer system performs processing of step S7.

In step S7, the user, the automatic transfer device, or the like takes out the sample holder 102 to which the TEM mesh is fixed from the lift-out device 2 and puts the sample holder 102 to the charged particle beam device 4.

In step S8, the charged particle beam device 4 receives the correction information of the TEM stage 5 calculated in step S5, and adjusts (corrects) an angle (α·β) and a height (Z) of the TEM stage 5 based on the received correction information. The angle (α·β) of the TEM stage 5 means an angle α of the TEM stage 5 with respect to an X-axis direction and an angle β of the TEM stage 5 with respect to a Y-axis direction in a three-dimensional orthogonal coordinate system having the X-axis, the Y-axis, and the Z-axis. The height (Z) means a position of the TEM stage 5 in the Z-axis direction.

In step S9, the charged particle beam device 4 performs fine adjustment of the angle (α·β) and the height (Z) of the TEM stage 5 using a phenomenon caused by the charged particle beam in order to perform correction more accurately than the adjustment of the angle (α·β) and the height (Z) of the TEM stage 5 in step S8. The adjustment of the angle may be performed by, for example, orientation adjustment using an electron diffraction phenomenon. For example, the adjustment of the angle may be performed by automatically and accurately adjusting the angle (α·β) of the TEM stage 5 to the crystal orientation of the lamella using an image of a diffraction pattern including a Kikuchi line. The adjustment of the height may be performed by performing multi-resolution analysis using wavelet transform or discrete wavelet transform to obtain a height distribution of the sample, and then adjusting the height (Z) of the TEM stage 5 using the obtained result.

After the coarse adjustment of the angle (α·β) and the height (Z) of the TEM stage 5 is performed in step S8, the fine adjustment of the angle (α·β) and the height (Z) of the TEM stage 5 is performed in step S9, thereby increasing an adjustable range of the angle (α·β) and height (Z) of the TEM stage 5 and is expected to shorten a time required for adjustment in step S9.

In step S10, in the TEM stage 5 whose angle (α·β) and height (Z) are adjusted in step S8 and step S9, the charged particle beam device 4 irradiates each lamella with the charged particle beam to perform imaging of each lamella.

By performing steps S1 to S10 in the imaging system 10, it is possible to observe the lamella in a state in which the angle (α·β) and the height (Z) are automatically adjusted in a short time. The adjustment of the angle and the height of the lamella is a necessary condition for performing accurate length measurement. Therefore, it can be said that the present disclosure contributes to an improvement in a throughput of a series of steps in TEM imaging for the purpose of length measurement and defect observation of a semiconductor sample.

### <Function of Device-to-Device Cooperation Software>

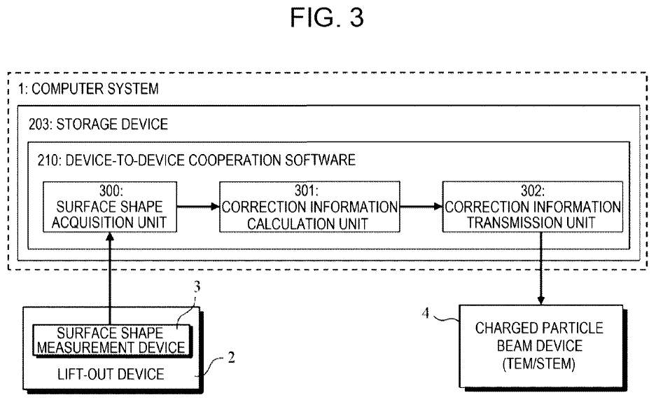

FIG. 3 is a functional block diagram of the device-to-device cooperation software according to the first embodiment. Functions of the device-to-device cooperation software 210 will be described with reference to FIG. 3. The device-to-device cooperation software 210 includes a surface shape acquisition unit 300 that acquires measurement data of surface shapes of the TEM mesh and the lamella from the surface shape measurement device 3, a correction information calculation unit 301 that calculates the correction information for adjusting the angle and the height of the TEM stage 5 based on the surface shape acquisition unit 300, and a correction information transmission unit 302 that transmits the correction information calculated by the correction information calculation unit 301 to the charged particle beam device 4.

### <Data Stored in Storage Device>

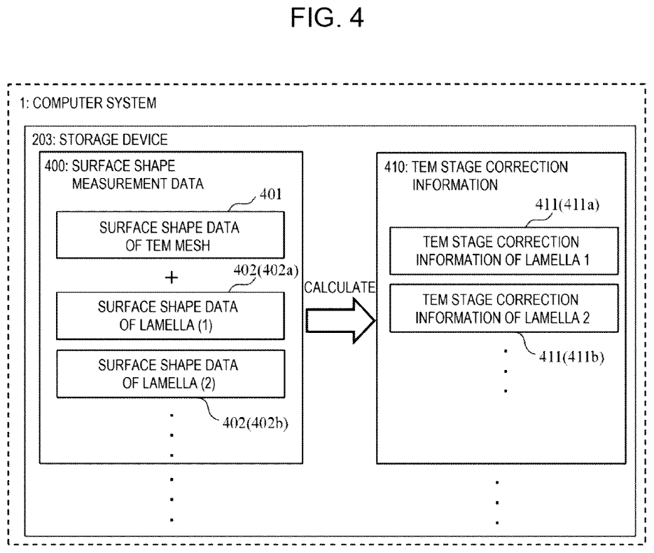

FIG. 4 is a configuration diagram of data stored in the storage device of the computer system according to the first embodiment. As shown in FIG. 4, the storage device 203 stores surface shape measurement data 400 and TEM stage correction information 410. The surface shape measurement data 400 includes surface shape data 401 indicating the surface shape of the entire TEM mesh measured in step S2 of FIG. 2 and surface shape data 402 indicating the surface shape of each lamella measured in step S4. The computer system 1 calculates TEM stage correction information 411 of each lamella based on the surface shape measurement data 400. The computer system 1 calculates correction information 411a for adjusting the angle and the height of the TEM stage 5 when imaging a lamella (1) based on, for example, surface shape data 401 indicating the surface shape of the entire TEM mesh and surface shape data 402a indicating the surface shape of the lamella (1), and stores the correction information 411a in the storage device 203. The computer system 1 calculates correction information 411b for adjusting the angle and the height of the TEM stage 5 when imaging a lamella (2) based on, for example, surface shape data 401 indicating the surface shape of the entire TEM mesh and surface shape data 402b indicating the surface shape of the lamella (2) different from the lamella (1), and stores the correction information 411b in the storage device 203. The TEM stage correction information 410 stores the correction information 411 for each lamella.

### <Calculation Method of Correction Information for TEM Stage 5>

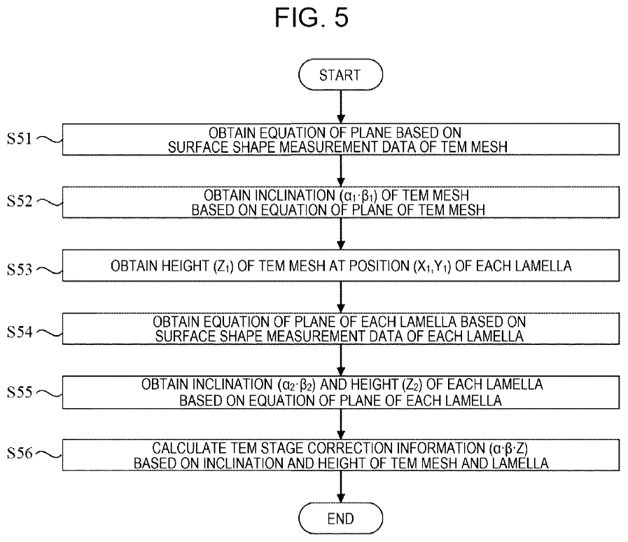

FIG. 5 is a flowchart showing a calculation method for calculating the TEM stage correction information based on the surface shape measurement data according to the first embodiment. The calculation method of FIG. 5 is based on an assumption that warping of the TEM mesh and the lamella is small and can be approximated by a plane. The equation of the plane may be based on either a substrate portion (metal) or a film portion of the TEM mesh.

In step S51, the computer system 1 obtains parameters a₁, b₁, c₁, and d₁ of an equation of a plane that approximates the surface of the TEM mesh, shown in the following formula (1), based on the surface shape measurement data of the TEM mesh.

$${a}_{1} x + {b}_{1} y + {c}_{1} z = {d}_{1} \qquad ( 1 )$$

There are various methods for obtaining the equation of the plane based on the surface shape measurement data. For example, a method for detecting a position of the mesh based on the surface shape measurement data by using image processing such as template matching, and obtaining the equation of the plane from three pre-designated points on the TEM mesh, and the like are conceivable.

For the three pre-designated points in the above, it is possible to automatically select a good condition by using a random sample consensus (RANSAC) method. Specifically, an equation of a tentative plane is obtained for any three points on the mesh, and then the number of all surface shape measurement data points (consensus) on the TEM mesh whose distance to the tentative plane is within a threshold value is counted. By repeating the above a plurality of times and employing the equation of the plane where the consensus is obtained most, the equation of the plane of the mesh with higher approximation accuracy can be obtained.

When obtaining the equation of the plane, spatial coordinates of a minimum of three points on the TEM mesh or lamella are required. However, when obtaining the equation of the plane with higher approximation accuracy using the RANSAC method or the like, it is necessary to have sufficient surface shape data. Therefore, also in the present method, it can be said that a surface shape measurement method such as CSI that can obtain a plurality of spatial coordinates on the TEM mesh or the lamella with sufficient spatial resolution is preferable.

In step S52, the computer system 1 obtains an angle of the TEM mesh (α₁·β₁). The angle of the TEM mesh (α₁·β₁) is obtained based on the equation of the plane (formula (1)) of the TEM mesh measured in step S51 using the following formulas (2-1) and (2-2).

$${α}_{1} = a tan ( - {b}_{1} / {c}_{1} ) \qquad ( 2 - 1 )$$

$${β}_{1} = a tan ( - {a}_{1} / {c}_{1} ) \qquad ( 2 - 2 )$$

In step S53, the computer system 1 obtains a height (Z₁) of the TEM mesh at a position (X₁, Y₁) of each lamella on an X-Y plane. The height (Z₁) of the TEM mesh is obtained based on the equation of the plane (formula (1)) of the TEM mesh measured in step S51 using the following formula (3).

$${Z}_{1} = ( {d}_{1} - {a}_{1} {X}_{1} - {b}_{1} {Y}_{1} ) / {c}_{1} \qquad ( 3 )$$

The angle (α₁) of the TEM mesh with respect to the X-axis direction, the angle (β₁) of the TEM mesh with respect to the Y-axis direction of the TEM mesh, and the height (Z₁) of the TEM mesh in the Z-axis direction obtained in steps S52 and S53 are used as the angle and the height to be used as the reference when measuring the surface shape of the lamella in the subsequent steps.

In step S54, the computer system 1 obtains the equation of the plane based on the surface shape measurement data of the lamella. The method for obtaining the equation of the plane is the same as in the case of the TEM mesh in step S51. A reference portion of the plane may be either a portion processed into a thin piece or a portion not processed into a thin piece.

In step S55, the computer system 1 obtains an angle (α₂·β₂) and a height (Z₂) of each lamella based on an equation of the plane of the lamella. The angle (α₂·β₂) of each lamella is obtained in the same manner as in the case of the TEM mesh in step S52. In addition, for the height (Z₂) of each lamella, a method for detecting an image of a thinned portion to be observed by the charged particle beam device 4 and obtaining a mean value or a median value of height data of the portion is considered.

In step S56, the computer system 1 obtains correction information (α·β·Z) for adjusting (correcting) the angle and the height of the TEM stage 5 based on the angle (α₁·β₁) and the height (Z₁) of the TEM mesh obtained in step S52 and step S53, and the angle (α₂·β₂) and the height (Z₂) of each lamella obtained in step S55. When the surface shape of the lamella is measured based on the TEM mesh, the correction information is obtained using the following formulas (4-1) to (4-3).

$$α = {α}_{1} + {α}_{2} + {α}_{offset} \qquad ( 4 - 1 )$$

$$β = {β}_{1} + {β}_{2} + {β}_{offset} \qquad ( 4 - 2 )$$

$$Z = {Z}_{1} + {Z}_{2} + {Z}_{offset} \qquad ( 4 - 3 )$$

The α_{offset}, β_{offset}, and Z_{offset} in the above formulas (4-1) to (4-3) are values obtained due to factors such as the angle of the TEM stage 5, and a deviation of a fixed position of a transport device that transports the lamella and the TEM stage 5. It is conceivable to determine in advance for each device, or determine a reference location on the TEM stage 5 by a method for performing calibration each time.

### Second Embodiment

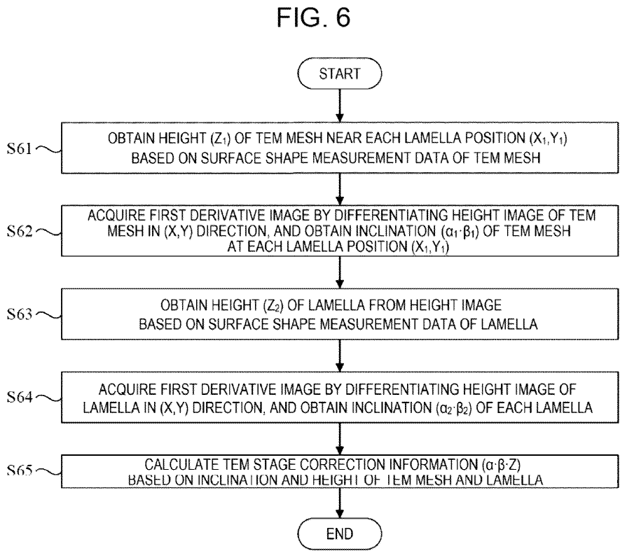

The method described in the first embodiment can be applied to a case in which the warping of the TEM mesh or the lamella is small. When the warping of the lamella is large, an error becomes large in the above method. In the second embodiment, a method for adjusting the angle and the height of the TEM stage 5 even when the warping of the lamella is large will be described. FIG. 6 is a flowchart showing a method for calculating TEM stage correction information based on surface shape measurement data according to a second embodiment.

### <Calculation Method of Position Correction Information>

In the second embodiment, it is assumed that a surface shape measurement device capable of acquiring a height image such as CSI is used as the surface shape measurement device 3. The height image is data in which a height (Z) of the lamella at a corresponding portion (X,Y) is held in a portion of a pixel value of normal image data. The height image may be subjected to preprocessing to remove noise using a Gaussian filter or a median filter.

In step S61, the computer system 1 obtains the height (Z₁) of the TEM mesh around each lamella position of the TEM mesh based on the surface shape measurement data of the TEM mesh. The position of the lamella is determined using image detection or the like. The height (Z₁) of the TEM mesh may be obtained based on a mean value or a median value of Z coordinates of several pixels around the lamella position.

In step S62, the computer system 1 obtains a first derivative image of the height image of the TEM mesh to obtain the angle (α₁·β₁) of the TEM mesh at each lamella position. The first derivative of the height image of the TEM mesh is performed in two directions of the X-axis direction and the Y-axis direction. Specific calculation methods include a method using numerical differentiation such as forward difference approximation using adjacent height values, or central difference approximation. At this time, the denominator term is a length per pixel (two pixels in the case of central difference approximation) in the X and Y-axis directions. For the angle obtained here, the angle α₁ in the X-axis direction and the angle β₁ in the Y direction can be obtained by calculating the value of atan in the same manner as in formulas (2-1) and (2-2). A mean value or a median value of several pixels around each lamella position (X₁,Y₁) may be used.

In step S63, the computer system 1 obtains a height (Z₂) of each lamella based on the surface shape measurement data of each lamella. The height (Z₂) of each lamella can be determined by detecting an image of an observation portion of the lamella and calculating the mean value or the median value of the height of the corresponding region.

In step S64, the computer system 1 obtains a first derivative image by differentiating the lamella height image in the (X,Y) direction, and determines the angle (α₂·β₂) of each lamella. A specific calculation procedure is the same as that in step S62.

In step S65, the computer system 1 calculates correction information (α·β·Z) for adjusting (correcting) the angle and the height of the TEM stage 5 based on the angle (α₁·β₁) of the TEM mesh and the angle (α₂·β₂) of each lamella, as well as the height (Z₁) of the TEM mesh and the height (Z₂) of each lamella. The calculation method is the same as that in step S56 of FIG. 5.

### Effects of First and Second Embodiments

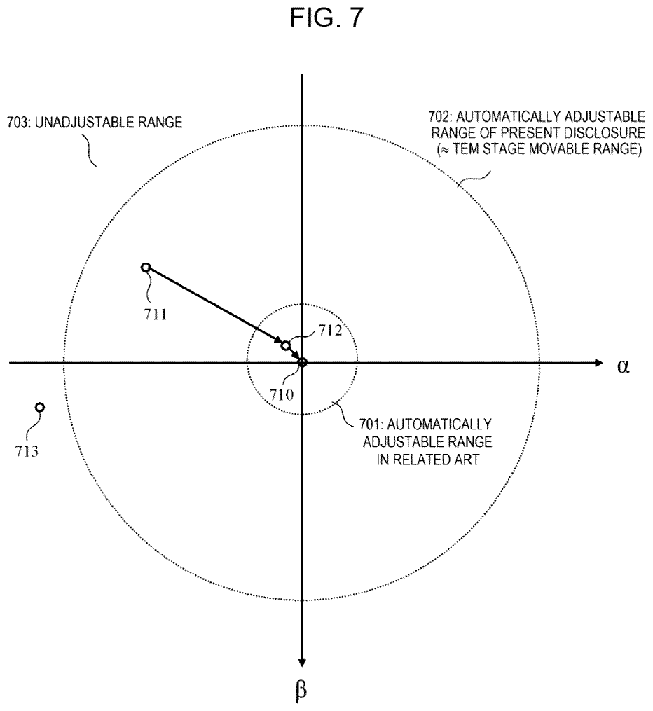

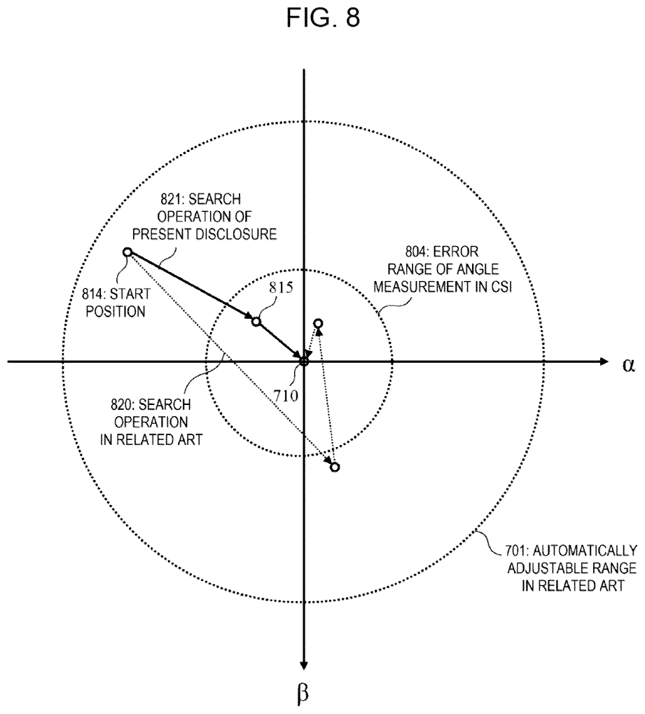

Next, effects achieved by the imaging system 10 according to the first embodiment and the second embodiment will be described with reference to FIGS. 7 and 8.

<Automatically Adjustable Range of Angle (a p)>

FIG. 7 is a diagram showing an automatically adjustable range of the angle (α·β) of the TEM stage. An origin 710 in FIG. 7 represents a point of the angle of the TEM stage 5 when imaging is performed, that is, the point at which the adjustment of the angle of the TEM stage 5 is completed.

An automatically adjustable range 701 of the angle (α·β) of the TEM stage 5 using an electron diffraction phenomenon in the related art is small compared to a range in which the TEM stage 5 is physically movable, and it is difficult to automatically correct the largely inclined lamella. In addition, it is not possible to determine whether the angle of the lamella is within the automatically adjustable range 701 before the automatic adjustment.

In the first and second embodiments, for example, even when a start position 711 for the angle of the lamella is within an automatically adjustable range (movable range of the TEM stage) 702 in the present disclosure, that is, in the case of a lamella with an angle larger than the automatically adjustable range 701 in the related art, by using the lamella angle (α₂·β₂) calculated based on the surface shape measurement data, it is possible to incline the TEM stage 5 to a position 712 within the automatically adjustable range 701 of the angle (α·β) of the TEM stage 5 using the electron beam diffraction phenomenon in the related art.

Further, when a start position 713 is in an unadjustable range 703, the lamella inclined beyond the movable range of the TEM stage 5 or an angle measurable range of the surface shape measurement device can be excluded from an observation target in advance. This can be said to be advantageous in improving the throughput as compared with the related art in which it is not possible to determine whether the lamella is largely deviated from the automatically adjustable range until the automatic adjustment is performed.

### <Search Operation for Automatic Adjustment Speed of Angle (α·β) of TEM Stage>

FIG. 8 is a diagram showing an operation of the automatic adjustment of the angle (α·β) of the TEM stage. Here, a point that contributes to the improvement in the throughput of observation even within the automatically adjustable range 701 in the related art shown in FIG. 8 will be described.

In the case of the automatic adjustment using the electron beam diffraction phenomenon in the related art, the greater the deviation from a target angle, the greater a measurement error in the angle deviation due to reasons such as a decrease in the number of diffraction spots. Therefore, a search operation is performed in which the angle deviation is calculated a plurality of times, such as along a search route 820 from a start point 814, to approach a target position 710.

On the other hand, in the first and second embodiments, by obtaining the angle of the lamella based on the surface shape of the lamella in advance, it is possible to align from a start point to a position 815 within an error range 804 of the angle measured based on the surface shape at the first time, as shown in a search route 821. Accordingly, it is possible to shorten the time of the search operation as compared to the related art.

### <Search Operation of Automatic Adjustment Speed of Height (Z)>

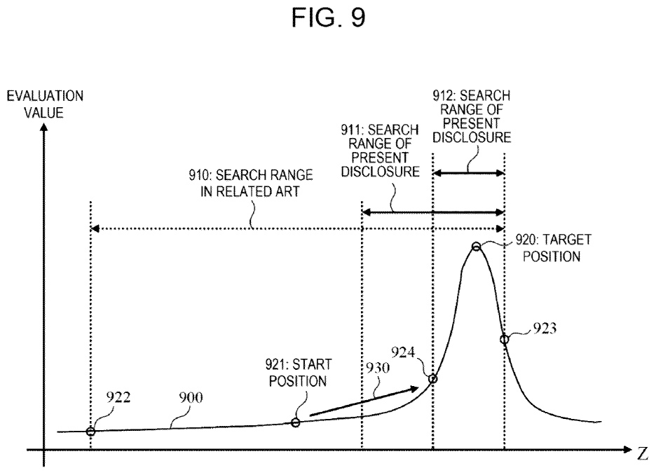

FIG. 9 is a diagram showing a search operation for adjusting a lamella height. The Z-axis direction of the charged particle beam device 4 is generally achieved by obtaining a value of the height (Z) at which an evaluation value obtained from an image is maximum (or minimum) by the method of multi-resolution analysis or the like based on the wavelet transform or the discrete wavelet transform.

As shown in the graph, an evaluation value 900 calculated by the above method tends to have a small change when a distance from a target position 920 is large. Therefore, for example, when a start position 921 is in a search range 910 in the related art, it cannot be determined whether the target position 920 is in±directions of the Z-axis. Here, it is necessary to perform scanning in an appropriate range in both + and − directions from a start position 922 to an end position 923 and search for the value of Z at which the evaluation value is maximum.

In the first and second embodiments, a movement 930 from the start position 921 to a position 924 closer to the target height can be performed by obtaining the height correction information based on the surface shape. Since it is only necessary to perform the search within a range of error during height measurement of the surface shape measurement device from the position 924, the search range can be reduced, and an improvement in the throughput is expected.

Among the surface shape measurement devices 3, the CSI is particularly excellent in spatial resolution in the Z-axis direction, and thus an effect of reducing the search range in adjustment of the position (height) in the Z-axis direction is particularly large.

Further, when a sufficient change (gradient) in the evaluation value is obtained in the vicinity of the start point 924 described in the present disclosure, it is possible to narrow down the search direction to one direction. That is, the adjustment can be performed in a search range 912 smaller than a search range 911.

The present disclosure is not limited to the above-described embodiments, and includes various modifications. For example, the embodiments described above are described in detail in order to describe the present disclosure in an easy-to-understand manner, and are not necessarily limited to including all the described configurations. In addition, another configuration can be added to, deleted from, or replaced with a part of a configuration of each embodiment.

For example, in the first and second embodiments, the angle and the height of the lamella are corrected based on the three-dimensional coordinate information measured by the surface shape measurement device 3, but at least one of the angle or the height of the lamella may be corrected. In this case, for example, the angle or the height of the lamella which is not corrected may be corrected using the phenomenon caused by the charged particle beam as in step S9 of FIG. 2.

### REFERENCE SIGNS LIST

1: computer system
2: lift-out device
3: surface shape measurement device
4: charged particle beam device
5: TEM stage
10: imaging system

1. An imaging system comprising:
a surface shape measurement device configured to measure three-dimensional coordinate information of a surface shape of a lamella having a laminated structure;
a computer system configured to calculate, based on the three-dimensional coordinate information measured by the surface shape measurement device, correction information for correcting an angle and a height of the lamella during imaging of the lamella, and to transmit the calculated correction information; and
a charged particle beam device configured to receive the correction information, correct the angle and the height of the lamella based on the correction information, and irradiate the lamella of which the angle and the height are corrected with a charged particle beam to image the lamella.

2. The imaging system according to claim 1, wherein
the surface shape measurement device measures three-dimensional coordinate information of a surface shape of a mesh on which a plurality of the lamellae are allowed to be placed, and the three-dimensional coordinate information of each of the surface shapes of the lamellae placed on the mesh, and
the computer system calculates the correction information based on the three-dimensional coordinate information of the surface shape of the mesh and the three-dimensional coordinate information of the surface shape of the lamella.

3. The imaging system according to claim 2, wherein
the computer system calculates, based on the three-dimensional coordinate information of a surface shape of a first lamella measured by the surface shape measurement device and the three-dimensional coordinate information of the surface shape of the mesh, first correction information for correcting an angle and a height of the first lamella when imaging the first lamella, and calculates, based on the three-dimensional coordinate information of a surface shape of a second lamella different from the first lamella measured by the surface shape measurement device and the three-dimensional coordinate information of the surface shape of the mesh, second correction information for correcting an angle and a height of the second lamella when imaging the second lamella.

4. The imaging system according to claim 2, wherein
the computer system calculates, based on the three-dimensional coordinate information of a surface shape of a first lamella measured by the surface shape measurement device and the three-dimensional coordinate information of the surface shape of the mesh at a position where the first lamella is placed, first correction information for correcting an angle and a height of the first lamella when imaging the first lamella, and calculates, based on the three-dimensional coordinate information of a surface shape of a second lamella different from the first lamella measured by the surface shape measurement device and the three-dimensional coordinate information of the surface shape of the mesh at a position where the second lamella is placed, second correction information for correcting an angle and a height of the second lamella when imaging the second lamella.

5. The imaging system according to claim 1, wherein
the surface shape measurement device obtains the three-dimensional coordinate information of at least three or more points on the lamella, and calculates the correction information based on the three-dimensional coordinate information of the at least three or more points.

6. The imaging system according to claim 1, wherein
the surface shape measurement device is a white light interference microscope.

7. The imaging system according to claim 1, wherein
the charged particle beam device further corrects the angle of the lamella by utilizing a diffraction phenomenon caused by the charged particle beam, and images the lamella after correcting the angle and the height of the lamella based on the correction information.

8. An imaging method comprising:
measuring, by a surface shape measurement device, three-dimensional coordinate information of a surface shape of a lamella having a laminated structure;
calculating, by a computer, based on the three-dimensional coordinate information measured by the surface shape measurement device, correction information for correcting an angle and a height of the lamella during imaging of the lamella, and transmitting the calculated correction information to a charged particle beam device; and
receiving, by the charged particle beam device, the correction information, correcting the angle and the height of the lamella based on the correction information, and irradiating the lamella of which the angle and the height are corrected with a charged particle beam to image the lamella.

9. The imaging method according to claim 8, further comprising:
measuring, by the surface shape measurement device, three-dimensional coordinate information of a surface shape of a mesh on which a plurality of the lamellae are allowed to be placed, wherein
the calculating of the correction information includes calculating the correction information based on the three-dimensional coordinate information of the surface shape of the mesh and the three-dimensional coordinate information of the surface shape of the lamella placed on the mesh.

10. The imaging method according to claim 9, wherein
the calculating of the correction information includes calculating, based on the three-dimensional coordinate information of a surface shape of a first lamella measured by the surface shape measurement device and the three-dimensional coordinate information of the surface shape of the mesh, first correction information for correcting an angle and a height of the first lamella when imaging the first lamella, and calculating, based on the three-dimensional coordinate information of a surface shape of a second lamella different from the first lamella measured by the surface shape measurement device and the three-dimensional coordinate information of the surface shape of the mesh, second correction information for correcting an angle and a height of the second lamella when imaging the second lamella.

11. The imaging method according to claim 9, wherein
the calculating of the correction information includes calculating, based on the three-dimensional coordinate information of a surface shape of a first lamella measured by the surface shape measurement device and the three-dimensional coordinate information of the surface shape of the mesh at a position where the first lamella is placed, first correction information for correcting an angle and a height of the first lamella when imaging the first lamella, and calculating, based on the three-dimensional coordinate information of a surface shape of a second lamella different from the first lamella measured by the surface shape measurement device and the three-dimensional coordinate information of the surface shape of the mesh at a position where the second lamella is placed, second correction information for correcting an angle and a height of the second lamella when imaging the second lamella.

12. The imaging method according to claim 8, wherein
the calculating of the correction information includes calculating the correction information based on the three-dimensional coordinate information of at least three or more points on the lamella.

13. The imaging method according to claim 8, wherein
the surface shape measurement device is a white light interference microscope.

14. The imaging method according to claim 8, further comprising:
further correcting, by the charged particle beam device, the angle of the lamella by utilizing a diffraction phenomenon caused by the charged particle beam after correcting the angle and the height of the lamella based on the correction information.
